(19) United States
(12) Patent Application Publication
(10) Pub. No.: US 2018/0315673 A1
(43) Pub. Date: Nov. 1, 2018

(54) SEMICONDUCTOR DEVICE AND METHOD OF MANUFACTURING THE SAME

(71) Applicant: RENESAS ELECTRONICS CORPORATION, Tokyo (JP)

(72) Inventors: Shigeya TOYOKAWA, Ibaraki (JP); Shuhei YAMAGUCHI, Ibaraki (JP); Koji HASEGAWA, Ibaraki (JP)

(21) Appl. No.: 15/954,121

(22) Filed: Apr. 16, 2018

(30) Foreign Application Priority Data
Apr. 27, 2017 (JP) 2017-088173

(51) Int. Cl. H01L 21/66; H01L 21/28; H01L 29/423

(52) U.S. Cl. CPC H01L 22/34; H01L 29/42372; H01L 21/28123; H01L 22/12

(57) ABSTRACT

A semiconductor chip has an evaluation pattern that is included in a monitor pattern. This evaluation pattern is constituted by a first pattern and a second pattern opposite to each other in an X direction. Further, the first pattern is constituted by a convex shape protruding in a direction away from the second pattern in the X direction.

### CROSS-REFERENCE TO RELATED APPLICATION

The present application claims priority from Japanese Patent Application No. 2017-088173 filed on Apr. 27, 2017, the content of which is hereby incorporated by reference into this application.

### TECHNICAL FIELD OF THE INVENTION

The present invention relates to a semiconductor device and a manufacturing technique of the same, and relates to a technique effectively applied to, for example, a miniaturized semiconductor device in which a pattern defect may become apparent.

### BACKGROUND OF THE INVENTION

International Publication No. WO2006-098023 (Patent Document 1) has described a technique relating to a testing circuit or a testing pattern known as TEG (Test Element Group).

### SUMMARY OF THE INVENTION

For example, in order to achieve a highly integrated and miniaturized semiconductor device, a device structure and a wiring structure configuring the semiconductor device are miniaturized. In this regard, as semiconductor devices are further miniaturized, a pattern defect is likely to occur in a patterning process that uses a photolithography technique. Thus, a pattern defect that becomes apparent as the semiconductor device is miniaturized is desired to be detected with high accuracy.

Other problems and novel features will be apparent from the description in the present specification and the attached drawings.

According to an embodiment of the present invention, a semiconductor device includes a monitor pattern. This monitor pattern has an evaluation pattern constituted by a first pattern and a second pattern opposite to each other in a first direction. Further, the first pattern is constituted by a convex shape protruding in a direction away from the second pattern in the first direction.

According to the above-described embodiment, a pattern defect can be detected with high accuracy.

### BRIEF DESCRIPTIONS OF THE DRAWINGS

FIG. 1 is a diagram showing a layout configuration of a semiconductor chip according to a first embodiment of the present invention;

FIG. 2 is a cross-sectional view showing a schematic device structure that includes a transistor and configures a logic circuit;

FIG. 3 is a cross-sectional view showing a manufacturing process of the semiconductor device according to the first embodiment;

FIG. 4 is a cross-sectional view showing the manufacturing process of the semiconductor device continued from FIG. 3;

FIG. 5 is a cross-sectional view showing the manufacturing process of the semiconductor device continued from FIG. 4;

FIG. 6 is a cross-sectional view showing the manufacturing process of the semiconductor device continued from FIG. 5;

FIG. 7 is a cross-sectional view showing the manufacturing process of the semiconductor device continued from FIG. 6;

FIG. 8 is a cross-sectional view showing the manufacturing process of the semiconductor device continued from FIG. 7;

FIG. 9 is a cross-sectional view showing the manufacturing process of the semiconductor device continued from FIG. 8;

FIG. 10 is a flowchart showing a process flow in forming a wiring;

FIG. 11 is a flowchart showing a process flow in testing for a pattern defect in a wiring pattern;

FIG. 12 is a schematic diagram showing a planar layout configuration of a monitor pattern according to a related art;

FIG. 13 is a photograph showing line-and-space patterns having a minimal line width and a minimal space width as an evaluation pattern;

FIG. 14 is a photograph showing fine dot patterns formed at a minimal space interval as an evaluation pattern;

FIG. 15A is a photograph showing a portion of a circuit pattern patterned at a best focus point;

FIG. 15B is a photograph showing a portion of another circuit pattern patterned in a state where the focal position is deviated;

FIG. 16 is a schematic diagram showing a planar layout configuration of a monitor pattern according to the first embodiment;

FIG. 17 is a schematic diagram showing an enlarged evaluation pattern formed on a portion within a region of FIG. 16;

FIG. 18 is a schematic diagram showing another enlarged evaluation pattern formed on a portion within the region of FIG. 16;

FIG. 19A is a photograph showing a portion of a circuit pattern patterned at a best focus point;

FIG. 19B is a photograph showing a first evaluation pattern patterned at the best focus point;

FIG. 19C is a photograph showing a second evaluation pattern patterned at the best focus point;

FIG. 20A is a photograph showing a portion of another circuit pattern patterned in a state where a focal position is deviated;

FIG. 20B is a photograph showing the first evaluation pattern patterned in the state where the focal position is deviated;

FIG. 20C is a photograph showing the second evaluation pattern patterned in the state where the focal position is deviated;

FIG. 21 is a schematic diagram showing a modification of the evaluation pattern;

FIG. 22 is a schematic diagram showing another modification of the evaluation pattern;

FIG. 23 is a schematic diagram showing another modification of the evaluation pattern;

FIG. 24 is a schematic diagram showing a one-shot region that indicates a single exposure region corresponding to a unit for one projection in an exposure process of a photolithography technique;

FIG. 25 is a schematic diagram showing an example of respectively arranging a plurality of monitor patterns within a predetermined number of chip regions; and

FIG. 26 is a schematic diagram showing an example of arranging a plurality of monitor patterns within a semiconductor chip (chip region).

### DESCRIPTIONS OF THE PREFERRED EMBODIMENTS

In the embodiments described below, the invention will be described in a plurality of sections or embodiments if necessary for the sake of convenience. However, these sections or embodiments are not irrelevant to each other unless otherwise clearly specified, and one section or embodiment partially or entirely corresponds to another section or embodiment as a modification, detailed or supplementary description, or the like.

In addition, in the embodiments described below, when referring to the number of a component (including number of pieces, numerical value, amount, and range), the number is not limited to a specified number and may be less than or greater than this number unless otherwise clearly specified or unless it is obvious from the context that the number is limited to the specified number in principle.

Furthermore, in the embodiments described below, it goes without saying that each component (including an element step) is not indispensable unless otherwise clearly specified or unless it is obvious from the context that the component is indispensable in principle.

Likewise, in the embodiments described below, when referring to a shape, a positional relation, or the like of a component, a substantially approximate shape, a similar shape, or the like is included unless otherwise clearly specified or unless it is obvious from the context that the shape, the positional relation, or the like of the component differs in principle. The same applies to the above-described numerical value and range.

In addition, in all of the drawings that describe the embodiments, the same members are generally denoted by the same reference symbols, and redundant descriptions thereof are omitted as appropriate. Note that, in order to easily view the drawings, hatched lines or stippled dots are occasionally used even if the drawing is a plan view.

### First Embodiment

<Layout Configuration of Semiconductor Chip>

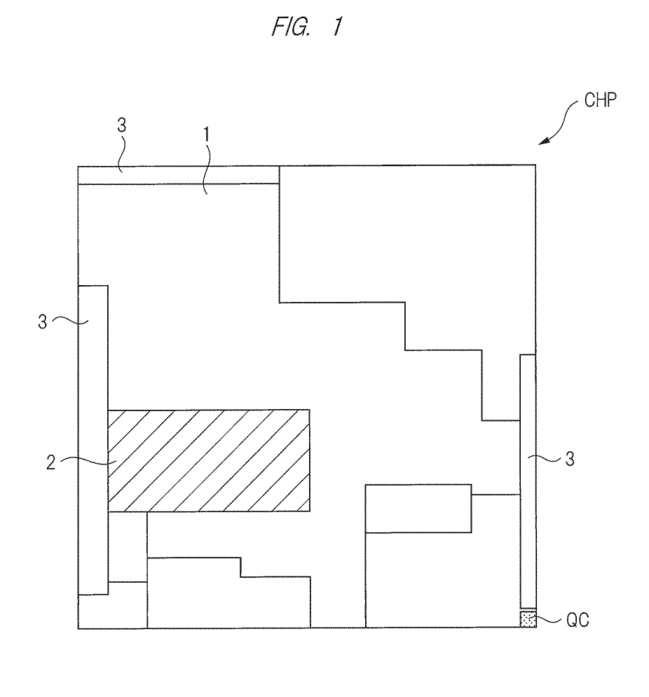

FIG. 1 is a diagram showing a layout configuration of a semiconductor chip CHP according to a first embodiment of the present invention. As shown in FIG. 1, the semiconductor chip CHP of the first embodiment is rectangular in shape and includes, for example, an analog circuit region in which an analog circuit 1 is formed, a logic circuit region in which a logic circuit 2 controlling the analog circuit 1 is formed, and an I/O circuit region in which an input/output circuit (I/O circuit) 3 is formed. Further, a monitor pattern QC is formed in the vicinity of a corner portion of the semiconductor chip CHP of the first embodiment.

<Device Structure>

Next, a device structure configuring the logic circuit 2 formed within the semiconductor chip CHP of the first embodiment will be described with reference to the drawings.

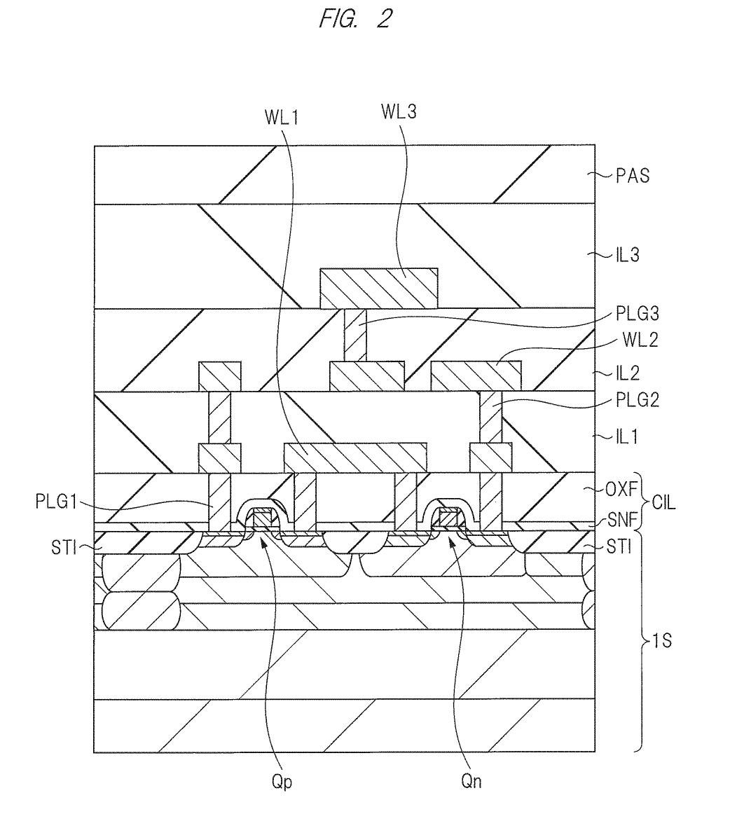

FIG. 2 is a cross-sectional view showing the schematic device structure that includes a transistor and configures the logic circuit 2. As shown in FIG. 2, an element isolation region STI is formed within a semiconductor substrate 1S, and a field-effect transistor is formed within an active region partitioned by this element isolation region STI. Specifically, FIG. 2 shows a CMOS transistor that is a basic component for configuring the logic circuit 2. Namely, as shown in FIG. 2, a p-channel type field-effect transistor Qp and an n-channel type field-effect transistor Qn are formed within the corresponding active region.

Further, a silicon nitride film SNF is formed over the semiconductor substrate 1S so as to cover the p-channel type field-effect transistor Qp and the n-channel type field-effect transistor Qn, and a silicon oxide film OXF is formed over this silicon nitride film SNF. A contact interlayer insulating film CIL is formed by the silicon nitride film SNF and the silicon oxide film OXF.

Subsequently, as shown in FIG. 2, a plug PLG1 is formed in the contact interlayer insulating film CIL so as to penetrate the contact interlayer insulating film CIL and reach a surface of the semiconductor substrate 1S. Specifically, each plug PLG1 is formed in the contact interlayer insulating film CIL so as to reach a source region and a drain region of the p-channel type field-effect transistor Qp and a source region and a drain region of the n-channel type field-effect transistor Qn.

Next, as shown in FIG. 2, a wiring WL1 made of, for example, an aluminum film or an aluminum alloy film is formed on the contact interlayer insulating film CIL in which the plug PLG1 is formed. Additionally, an interlayer insulating film IL1 made of, for example, a silicon oxide film is formed so as to cover the wiring WL1 formed on the contact interlayer insulating film CIL, and a plug PLG2 is formed in this interlayer insulating film IL1 so as to penetrate the interlayer insulating film IL1 and reach the wiring WL1.

Further, as shown in FIG. 2, a wiring WL2 made of, for example, an aluminum film or an aluminum alloy film is formed on the interlayer insulating film IL1 in which the plug PLG2 is formed. Additionally, an interlayer insulating film IL2 made of, for example, a silicon oxide film is formed over the interlayer insulating film IL1 so as to cover the wiring WL2, and a plug PLG3 is formed in this interlayer insulating film IL2 so as to penetrate the interlayer insulating film IL2. Next, a wiring WL3 is formed on the interlayer insulating film IL2 in which the plug PLG3 is formed, and an interlayer insulating film IL3 made of, for example, a silicon oxide film is formed so as to cover this wiring WL3. Further, a surface protective film (passivation film) PAS made of, for example, a silicon nitride film is formed over the interlayer insulating film IL3. In this manner, the logic circuit 2 having the device structure as shown in FIG. 2 is formed within the semiconductor chip CHP (see FIG. 1).

<Manufacturing Method of Device Structure>

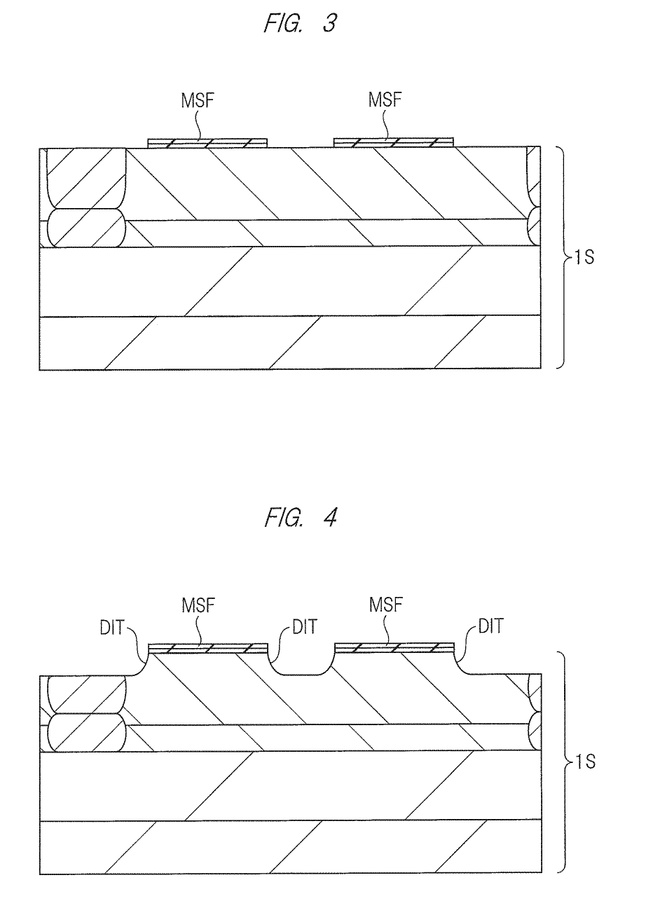

Next, a manufacturing method of the device structure formed within the semiconductor chip CHP will be described in a simplified manner with reference to the drawings. First, as shown in FIG. 3, the semiconductor substrate 1S is prepared. Then, a plurality of semiconductor regions are formed within the semiconductor substrate 1S by using, for example, a photolithography technique and an ion implantation process. Next, as shown in FIG. 3, after a silicon oxide film is formed over the surface of the semiconductor substrate 1S, a mask film MSF made of a silicon nitride film is formed over this silicon oxide film. Then, the mask film MSF is patterned by using, for example, the photolithography technique and an etching technique. Next, a portion of the semiconductor substrate 1S is etched with using the patterned mask film MSF as a hard mask. As a result, as shown in FIG. 4, a trench DIT aligned with the mask film MSF is formed on the surface of the semiconductor substrate 1S. Then, after an insulating film (silicon oxide film) is formed so as to fill the trench DIT formed on the surface of the semiconductor substrate 1S, excessive insulating films formed over this surface are removed, so that the insulating film is left only inside the trench DIT. As a result, the element isolation region having a structure in which the trench DIT is filled with the insulating film can be formed. A region of the semiconductor substrate 1S partitioned by this element isolation region becomes the active region.

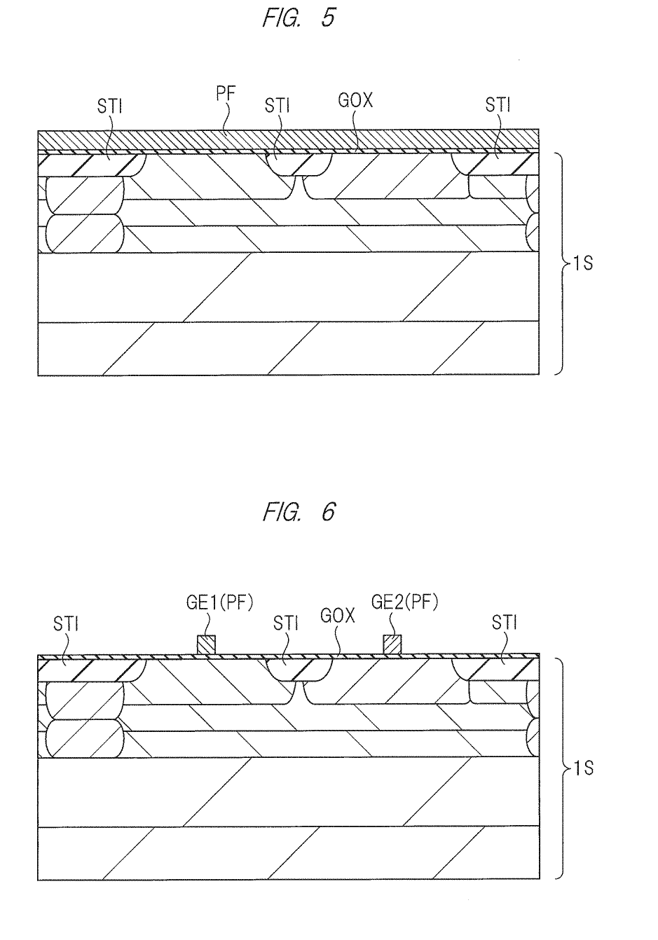

Next, as shown in FIG. 5, after a gate insulating film GOX made of, for example, a silicon oxide film is formed over the surface of the semiconductor substrate 1S, a polysilicon film PF is formed over the gate insulating film GOX. The polysilicon film PF can be formed by using, for example, a CVD (Chemical Vapor Deposition) process. Subsequently, although not shown, a dual-gate structure that is a structure capable of reducing a threshold voltage at both the p-channel type field-effect transistor and the n-channel type field-effect transistor is formed. For this purpose, a p-type impurity (acceptor) is implanted into the polysilicon film PF formed within a p-channel type field-effect transistor forming region, and an n-type impurity (donor) is implanted into the polysilicon film PF formed within an n-channel type field-effect transistor forming region by using, for example, the ion implantation process. Then, as shown in FIG. 6, the polysilicon film PF is patterned by using the photolithography technique and the etching technique. As a result, a gate electrode GE1 can be formed within the p-channel type field-effect transistor forming region, and a gate electrode GE2 can be formed within the n-channel type field-effect transistor forming region.

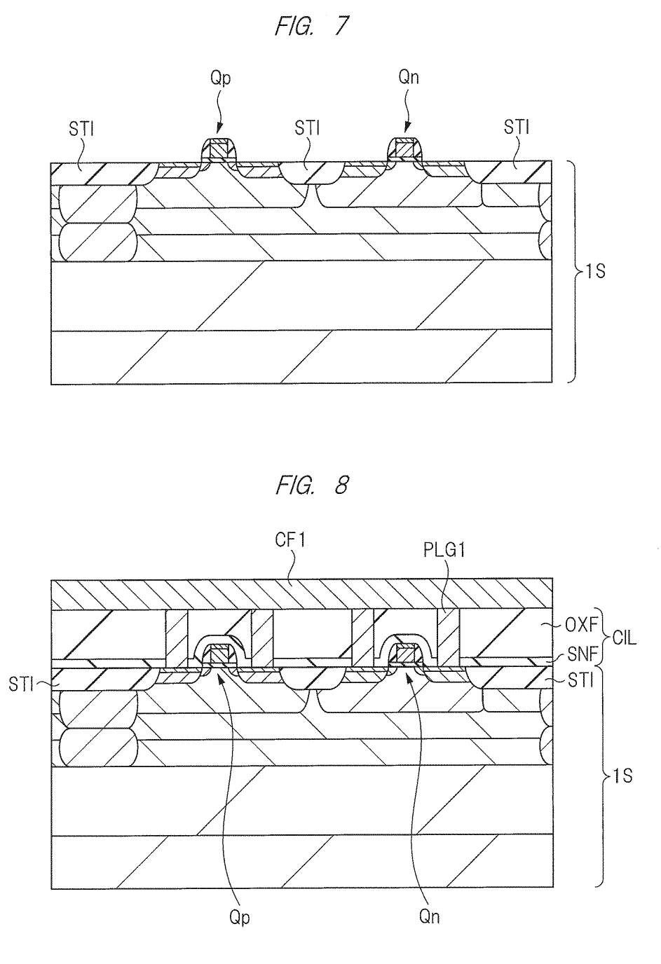

Subsequently, although not shown, an extension region aligned with the gate electrode GE1 is formed within the semiconductor substrate 1S, and an extension region aligned with the gate electrode GE2 is formed within the semiconductor substrate 15 by using, for example, the photolithography technique and the ion implantation process. Further, sidewall spacers made of, for example, a silicon oxide film are respectively formed on both sidewalls of the gate electrode GE1 and both sidewalls of the gate electrode GE2. Next, by using, for example, the photolithography technique and the ion implantation process, semiconductor regions configuring a portion of the source region and a portion of the drain region of the p-channel type field-effect transistor are formed within the semiconductor substrate 1S so as to be aligned with the sidewall spacers formed on both sidewalls of the gate electrode GE1. Likewise, by using the photolithography technique and the ion implantation process, semiconductor regions configuring a portion of the source region and a portion of the drain region of the n-channel type field-effect transistor are formed within the semiconductor substrate 15 so as to be aligned with the sidewall spacers formed on both sidewalls of the gate electrode GE2. Further, as shown in FIG. 7, a silicide film is formed in order to reduce resistance of the gate electrode GE1, the gate electrode GE2, each source region, and each drain region. In this manner, as shown in FIG. 7, the p-channel type field-effect transistor Qp can be formed within the p-channel type field-effect transistor forming region of the semiconductor substrate 1S, and the n-channel type field-effect transistor Qn can be formed within the n-channel type field-effect transistor forming region of the semiconductor substrate 1S.

Next, as shown in FIG. 8, the silicon nitride film SNF is formed so as to cover the p-channel type field-effect transistor Qp and the n-channel type field-effect transistor Qn formed on the semiconductor substrate 1S, and the silicon oxide film OXF is formed over this silicon nitride film SNF. The silicon nitride film SNF and the silicon oxide film OXF can be formed by using, for example, the CVD process. At this time, the contact interlayer insulating film CIL is formed by the silicon nitride film SNF and the silicon oxide film OXF.

Then, by using the photolithography technique and the etching technique, a contact hole is formed on the contact interlayer insulating film CIL so as to penetrate the contact interlayer insulating film CIL, and a tungsten film is formed over the contact interlayer insulating film CIL including an inside of this contact hole. Further, the excessive tungsten film formed over the contact interlayer insulating film CIL is removed by using, for example, a chemical mechanical polishing process, so that the tungsten film is left only inside the contact hole to form the plug PLG1 made of the tungsten film filled in the contact hole.

Next, as shown in FIG. 8, a conductive film CF1 is formed over the contact interlayer insulating film CIL in which the plug PLG1 is formed. This conductive film CF1 is made of, for example, an aluminum film or an aluminum alloy film and can be formed by using, for example, a sputtering process.

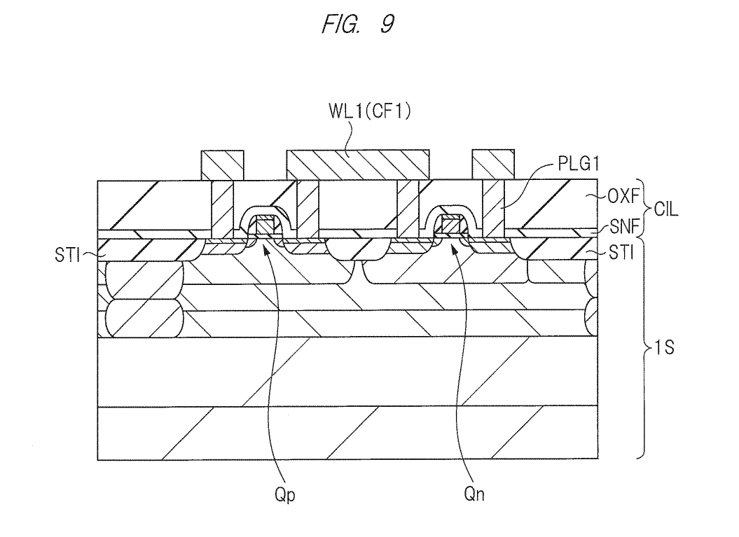

Subsequently, as shown in FIG. 9, the conductive film CF1 is patterned by using the photolithography technique and the etching technique to form the wiring WL1. Descriptions of subsequent steps will be omitted as appropriate. Thus, the device structure that includes the field-effect transistor and the wiring can be manufactured in this manner.

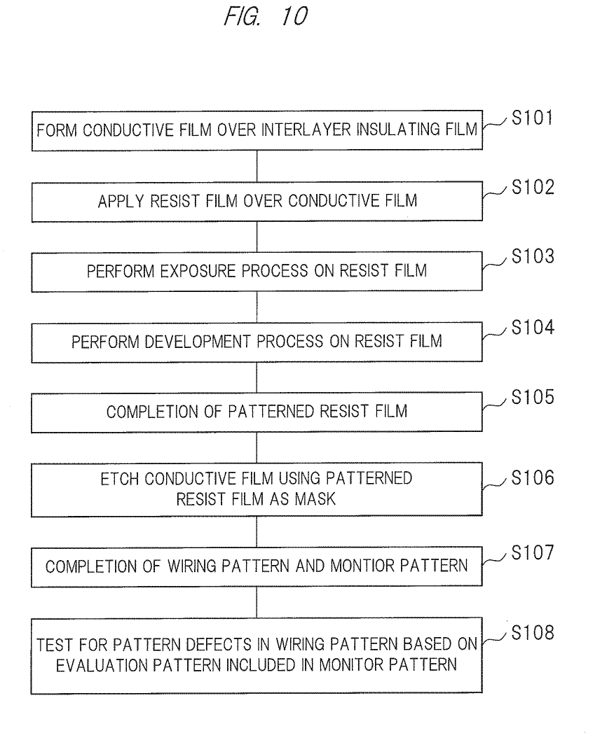

Now, directing attention to a forming process for the wiring WL1 that is a first layer wiring, this forming process will be described in detail. FIG. 10 is a flowchart showing a process flow informing the wiring WL1. First, in FIG. 10, the conductive film (conductive film CF1) is formed over the interlayer insulating film (contact interlayer insulating film CIL) (S101). This conductive film is made of, for example, an aluminum film or an aluminum alloy film, and can be formed by using, for example, the sputtering process.

Next, a resist film is applied over the conductive film by using, for example, a spin-coating process (S102). Then, an exposure process is performed on the resist film applied over the conductive film (S103). Next, a development process is performed on the resist film on which the exposure process was performed (S104). As a result, patterning of the resist film is completed (S105).

Subsequently, the conductive film is etched with using the patterned resist film as a mask (S106). As a result, a wiring pattern (wiring) and a monitor pattern composed of the patterned conductive film can be formed (S107). Next, the wiring pattern is tested for occurrence of a pattern defect based on an evaluation pattern included in the monitor pattern (S108).

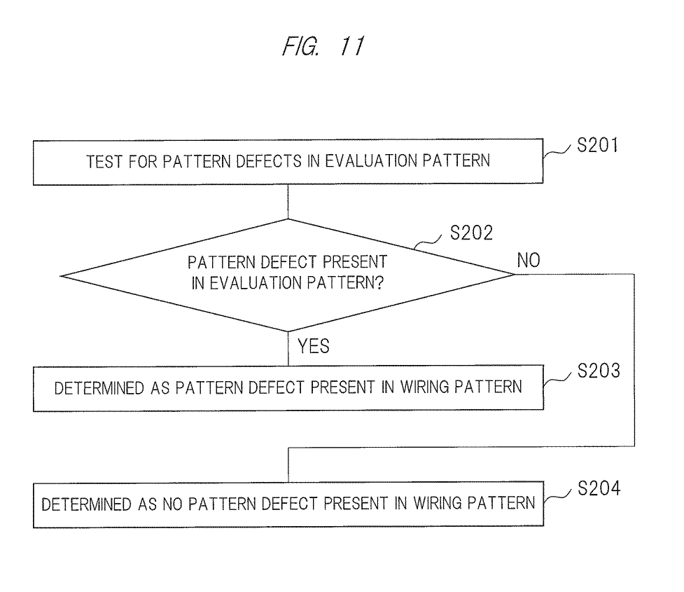

Hereinafter, a process in testing for a pattern defect in the wiring pattern will be described. FIG. 11 is a flowchart showing a process flow in testing for a pattern defect in the wiring pattern. First, as shown in FIG. 11, the evaluation pattern included in the monitor pattern is tested for presence of a pattern defect (S201). For example, if patterns which should be formed apart from each other are formed so as to be bridged, it is considered that a pattern defect corresponding to a short-circuit failure is present. Here, it is determined whether a pattern defect is present or not present in the evaluation pattern included in the monitor pattern (S202). At this time, if a pattern defect is present in the evaluation pattern, it is determined that a pattern defect is present in the wiring pattern formed in the same step as the evaluation pattern (S203). On the other hand, if a pattern defect is not present in the evaluation pattern, it is determined that a pattern defect is not present in the wiring pattern formed in the same step as the evaluation pattern (S204). In this manner, it is determined in the first embodiment whether a pattern defect is occurring or not occurring in the wiring pattern by testing for presence or non-presence of a pattern defect in the evaluation pattern included in the monitor pattern formed in the same step as the wiring pattern. Therefore, it is clear that the selection of the evaluation pattern included in the monitor pattern is important in testing for a pattern defect in the wiring pattern.

<Importance of Evaluation Pattern>

As described above, it can be seen that, when attention is directed to, for example, a wiring process in the first embodiment, the monitor pattern which is not a product pattern is formed in the same step as the wiring pattern partially configuring the product pattern, and the wiring pattern is tested for occurrence of a pattern defect by testing for occurrence or non-occurrence of a pattern defect in the evaluation pattern included in the monitor pattern. Therefore, it is important that the evaluation pattern included in the monitor pattern is a pattern capable of exactly reflecting a pattern defect in the wiring pattern. Namely, it is important that a correspondence relation in which a pattern defect always occurs in the wiring pattern when a pattern defect occurs in the evaluation pattern and a correspondence relation in which a pattern defect does not occur in the wiring pattern when a pattern defect does not occur in the evaluation pattern are satisfied from the viewpoint of detecting a pattern defect in the wiring pattern with high accuracy.

The following description will first explain that the correspondence relation between the evaluation pattern and a portion of the product pattern formed in the same step is not always satisfied in the related art in regards to detecting a pattern defect with high accuracy. Thereafter, room for improvement of the related art and a technical idea of the devised first embodiment will be described.

<Description of Related Art>

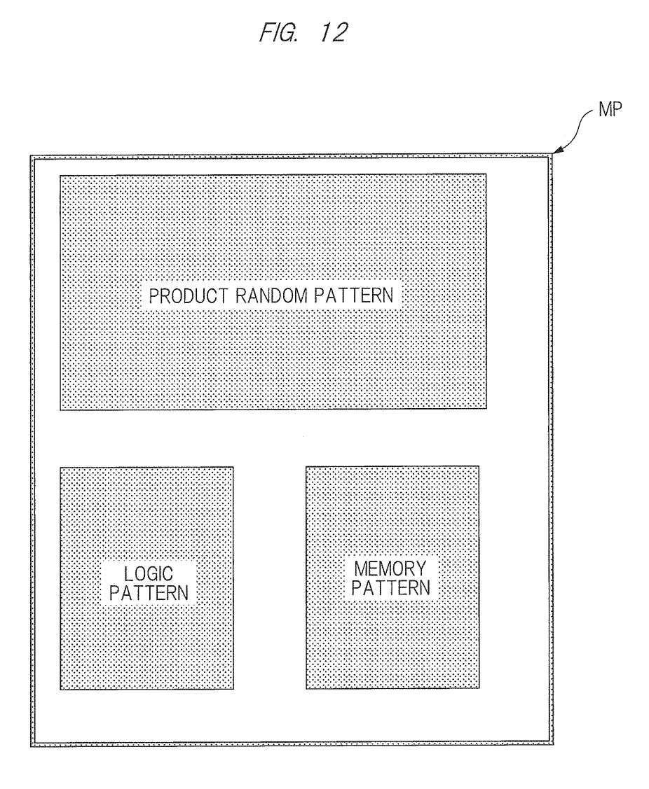

FIG. 12 is a schematic diagram showing a planar layout configuration of a monitor pattern MP according to the related art. As shown in FIG. 12, although the monitor pattern MP of the related art includes various types of patterns represented by a product random pattern, a logic pattern, and a memory pattern, the actual testing process will use a portion of the evaluation pattern included in the monitor pattern to perform tests for a pattern defect in a portion of the product pattern formed in the same step as the monitor pattern.

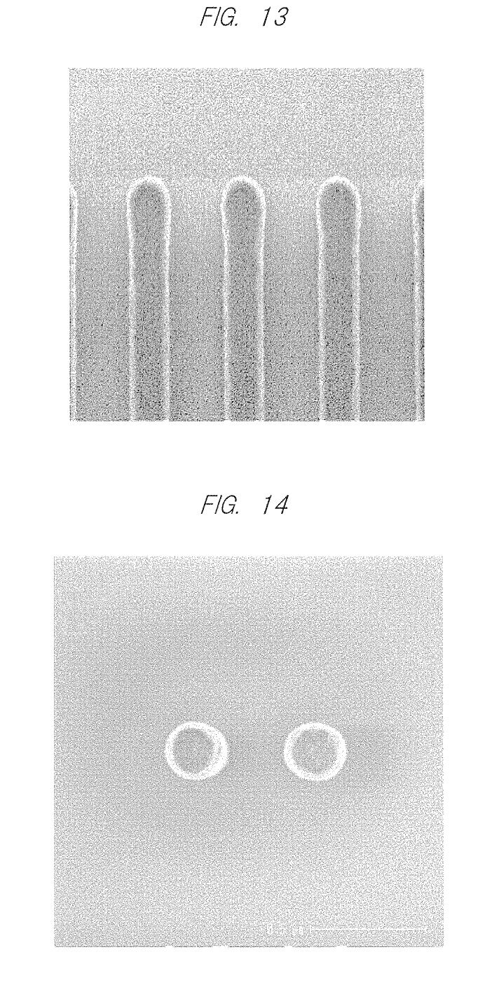

For example, FIG. 13 shows line-and-space patterns each having a minimal line width and a minimal space width being used as the evaluation pattern. Namely, the line-and-space patterns having the minimal line width and the minimal space width are most likely to be bridged and cause a pattern defect, and thus, it is considered that occurrence of a pattern defect in the product pattern can be detected with high accuracy by using the line-and-space patterns having the minimal line width and the minimal space width as the evaluation pattern.

In addition, for example, FIG. 14 shows fine dot patterns formed at a minimal space interval being used as the evaluation pattern. In this case also, the fine dot patterns are likely to be bridged and cause a pattern defect, and thus, it is considered that occurrence of a pattern defect in the product pattern can be detected with high accuracy by using the fine dot patterns formed at the minimal space interval as the evaluation pattern.

As described above, in the related art, the product pattern is tested for occurrence of a pattern defect by using the line-and-space patterns shown in FIG. 13 or the fine dot patterns shown in FIG. 14 as the evaluation pattern.

<Studies on Improvements>

However, studies by the present inventors have found that it is difficult to detect occurrence of a pattern defect in the product pattern with high accuracy by using only the line-and-space patterns shown in FIG. 13 or the fine dot patterns shown in FIG. 14 as the evaluation pattern, and this finding will be described below.

In the related art, a testing process is adopted such that when a pattern defect occurs in the line-and-space patterns shown in FIG. 13 or in the fine dot patterns shown in FIG. 14, it is determined that a pattern defect is occurring in a portion of the product pattern.

Here, according to the studies by the present inventors, it was found that when a focal position is deviated in, for example, the exposure process of the photolithography technique, a first pattern and a second pattern of the product pattern, which should be formed apart from each other, are undesirably bridged and cause a pattern defect to occur in the product pattern. However, even if the focal position was deviated, a pattern defect did not occur in either the line-and-space patterns shown in FIG. 13 or the fine dot patterns shown in FIG. 14. This means that if the line-and-space patterns shown in FIG. 13 or the fine dot patterns shown in FIG. 14 were adopted as the evaluation pattern, it would be difficult to detect a pattern defect in a portion of the product pattern based on the presence or non-presence of a pattern defect in this evaluation pattern. This is because, in a situation where a pattern defect occurs in a portion of the product pattern but does not occur in the line-and-space patterns shown in FIG. 13 or the fine dot patterns shown in FIG. 14, testing for a pattern defect in the product pattern based on the evaluation pattern would hold no meaning.

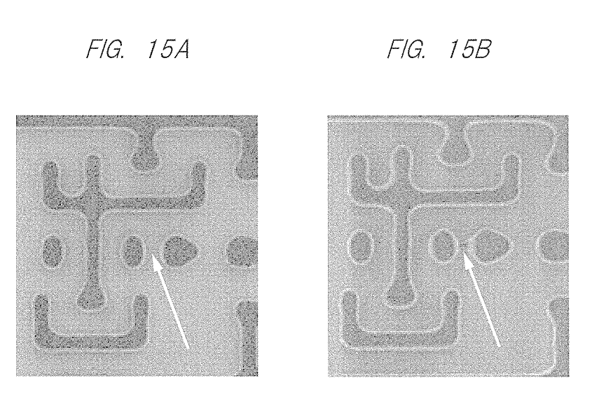

Namely, the present inventors have found that the product pattern includes a portion in which a pattern defect is more likely to occur than the line-and-space patterns shown in FIG. 13 or the fine dot patterns shown in FIG. 14. In other words, it became clear that the product pattern includes a shape that is more sensitive to focal position deviation than the line-and-space patterns shown in FIG. 13 or the fine dot patterns shown in FIG. 14. In this case, it is difficult to detect a pattern defect in the product pattern with high accuracy by using only the line-and-space patterns shown in FIG. 13 or the fine dot patterns shown in FIG. 14 of the related art as the evaluation pattern. For example, FIG. 15A is a photograph showing a portion of a circuit pattern patterned at a best focus point, and it can be seen in FIG. 15A that the patterns are separate from each other at a location indicated by an arrow. On the other hand, FIG. 15B is a photograph showing a portion of another circuit pattern patterned in a state where the focal position is deviated. It can be seen in FIG. 15B that the patterns which should be separate from each other are bridged at a location indicated by an arrow, thereby causing a pattern defect.

In the above-described related art, the correspondence relation between the evaluation pattern included in the monitor pattern and the product pattern is insufficient in regards to detecting a pattern defect, and there is room for improvement in that a pattern defect in the product pattern cannot be detected with high accuracy by using this evaluation pattern. Namely, there is room for improvement in that the related art does not adopt an evaluation pattern that is capable of detecting a pattern defect in the product pattern caused by focal position deviation with high accuracy.

Therefore, the first embodiment is devised such that a pattern defect in the product pattern caused by focal position deviation can be detected with high accuracy. The technical idea of the devised first embodiment will be described below.

<Monitor Pattern of First Embodiment>

First, a definition of “monitor pattern” according to the first embodiment will be described. In the first embodiment, the “monitor pattern” is defined as a pattern that is separate from the product pattern and has a shape corresponding to a portion of the product pattern. Further, the above-defined “monitor pattern” is formed on the semiconductor chip of the first embodiment in addition to the conventional product pattern. Additionally, the “monitor pattern” includes an “evaluation pattern” that is used to detect a pattern defect in the product pattern.

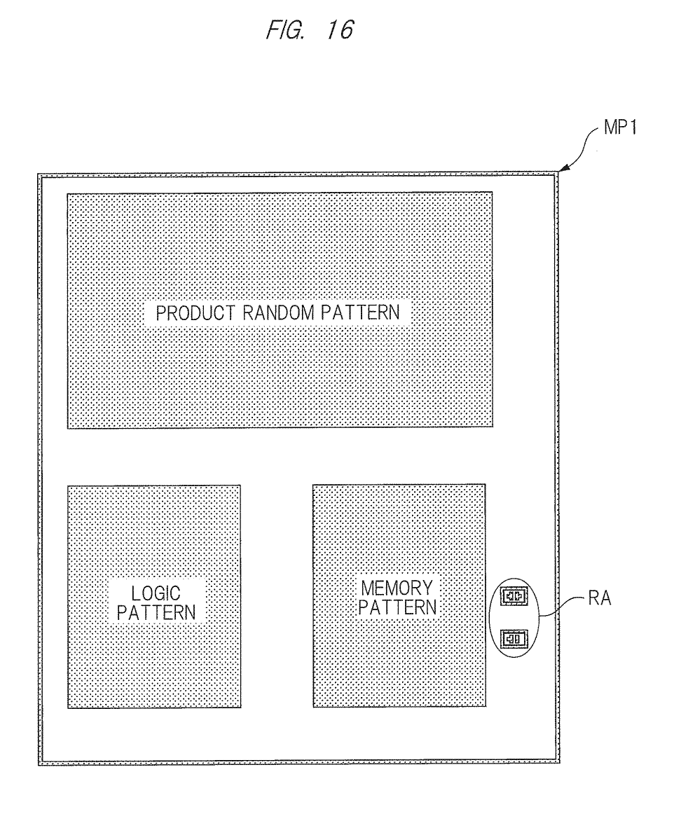

FIG. 16 is a schematic diagram showing a planar layout configuration of a monitor pattern MP1 according to the first embodiment. In FIG. 16, the monitor pattern MP1 of the first embodiment is provided with the evaluation pattern surrounded by a region RA in addition to the monitor pattern MP of the related art shown in FIG. 12. Other components and features of the monitor pattern MP1 of the first embodiment shown in FIG. 16 are equivalent to those of the monitor pattern MP of the related art shown in FIG. 12.

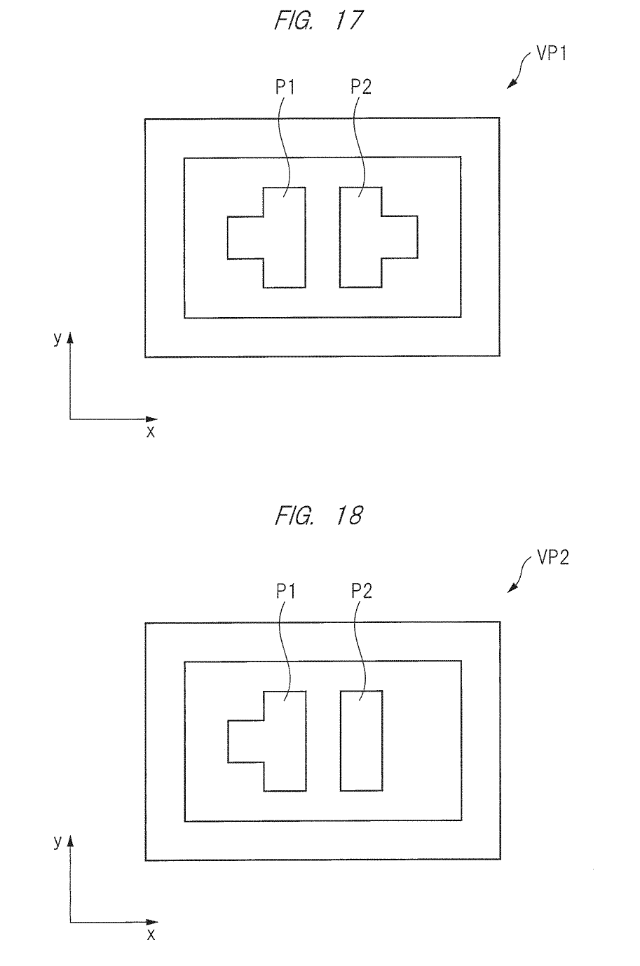

FIG. 17 is a schematic diagram showing an enlarged evaluation pattern VP1 formed within the region RA of FIG. 16. In FIG. 17, the evaluation pattern VP1 of the first embodiment is constituted by a pattern (first pattern) P1 and another pattern (second pattern) P2 opposite to each other in an X direction (first direction). At this time, the pattern P1 is composed of a convex shape protruding in a direction away from the pattern P2 in the X direction. On the other hand, the pattern P2 is composed of a convex shape protruding in a direction away from the pattern P1 in the X direction.

For example, in the first embodiment, the product pattern has a first layer wiring pattern (wiring WL1 of FIG. 2) formed above the semiconductor substrate 1S (see FIG. 2), and the monitor pattern is formed in the same layer as, for example, the first layer wiring pattern (wiring WL1 of FIG. 2).

FIG. 18 is a schematic diagram showing an enlarged evaluation pattern VP2 formed within the region RA of FIG. 16. In FIG. 18, the evaluation pattern VP2 of the first embodiment is constituted by a pattern (first pattern) P1 and another pattern (second pattern) P2 opposite to each other in the X direction (first direction). At this time, the pattern P1 is composed of a convex shape protruding in a direction away from the pattern P2 in the X direction. On the other hand, the pattern P2 is composed of a rectangular shape.

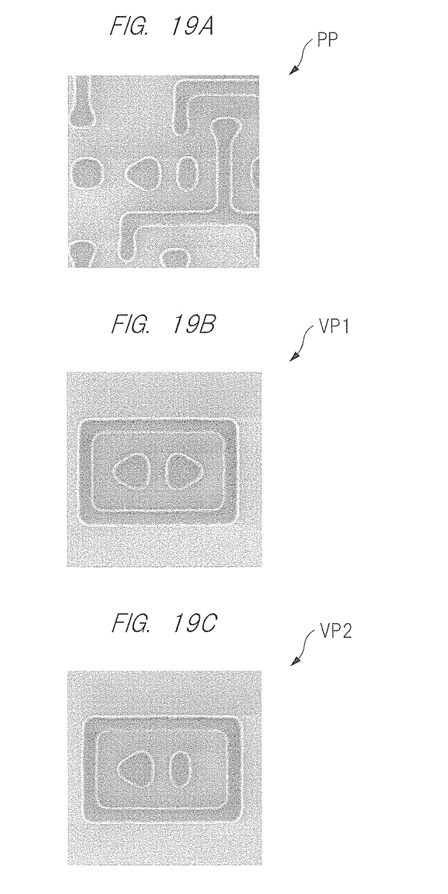

FIG. 19A is a photograph showing a portion of the circuit pattern patterned at the best focus point. On the other hand, FIG. 19B is a photograph showing the evaluation pattern VP1 patterned at the best focus point, and FIG. 19C is a photograph showing the evaluation pattern VP2 patterned at the best focus point. As shown in FIGS. 19A to 19C, it can be seen that a pattern defect does not occur in the portion of the circuit pattern PP as well as in the evaluation pattern VP1 and the evaluation pattern VP2 when patterned at the best focus point. Therefore, it can be seen that, when attention is first directed to patterning at the best focus point, the evaluation pattern VP1 and the evaluation pattern VP2 can be used to detect a pattern defect in a portion of the circuit pattern PP.

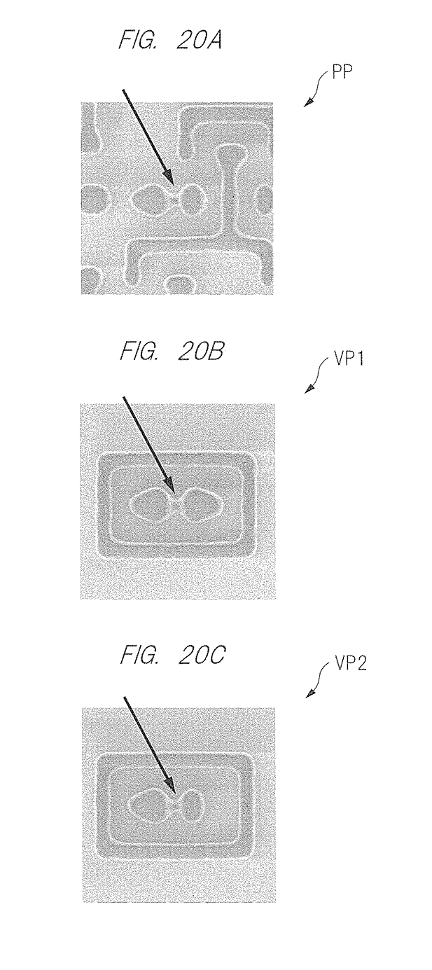

FIG. 20A is a photograph showing a portion of another circuit pattern PP patterned in a state where the focal position is deviated. On the other hand, FIG. 20B is a photograph showing the evaluation pattern VP1 patterned in the state where the focal position is deviated, and FIG. 20C is a photograph showing the evaluation pattern VP2 patterned in the state where the focal position is deviated. As shown in FIGS. 20A to 20C, it can be seen that a pattern defect occurs in the portion of the circuit pattern PP (indicated by an arrow in FIG. 20A) as well as in the evaluation pattern VP1 and the evaluation pattern VP2 (indicated by arrows in FIGS. 20B and 20C) when patterned in a state where the focal position is deviated. Therefore, it can be seen again that, when attention is directed to patterning in a state where the focal position is deviated, the evaluation pattern VP1 and the evaluation pattern VP2 can be used to detect a pattern defect in a portion of the circuit pattern PP.

From the above description, it can be seen that by using the evaluation pattern VP1 and the evaluation pattern VP2 added to the monitor pattern MP1 of the first embodiment for detecting a pattern defect in the circuit pattern PP, a pattern defect in the circuit pattern PP caused by focal position deviation can be detected with high accuracy.

<Feature of First Embodiment>

Next, a feature of the first embodiment will be described. The feature of the first embodiment is that the presence or non-presence of a pattern defect in a portion of the product pattern is detected by using the monitor pattern MP1 (see FIG. 16) that includes, for example, the evaluation pattern VP1 shown in FIG. 17 or the evaluation pattern VP2 shown in FIG. 18. Namely, the feature of the first embodiment is that it is determined that a pattern defect is present in a portion of the product pattern when a pattern defect is present in the evaluation pattern VP1 or the evaluation pattern VP2, whereas it is determined that a pattern defect is not present in the product pattern when a pattern defect is not present in the evaluation pattern VP1 or the evaluation pattern VP2. Hence, according to the feature of the first embodiment, the presence or non-presence of a pattern defect in a portion of the product pattern patterned in a state where the focal position is deviated can be detected with high accuracy. This is because the presence or non-presence of a pattern defect in, for example, the evaluation pattern VP1 and the evaluation pattern VP2 adopted in the first embodiment accurately coincides with the presence or non-presence of a pattern defect in a portion of the product pattern as shown in FIGS. 19A to 19C and FIGS. 20A to 20C.

In this manner, the technical significance of the feature of the first embodiment resides in finding the evaluation pattern that accurately reflects the presence or non-presence of a pattern defect in a portion of the product pattern caused by a slight deviation in the focal position, and accordingly, the presence or non-presence of a pattern defect in a portion of the product pattern can be detected with high accuracy.

In particular, as described above by way of example in the evaluation pattern VP1 shown in FIG. 17 and the evaluation pattern VP2 shown in FIG. 18, the first embodiment has a great technical significance in that it specifically provides the evaluation pattern that accurately reflects the presence or non-presence of a pattern defect in a portion of the product pattern caused by a slight deviation in the focal position. Namely, the feature of the first embodiment has a great technical significance in that a specific configuration capable of achieving a significant effect not achievable by the related art is provided together with a fundamental concept.

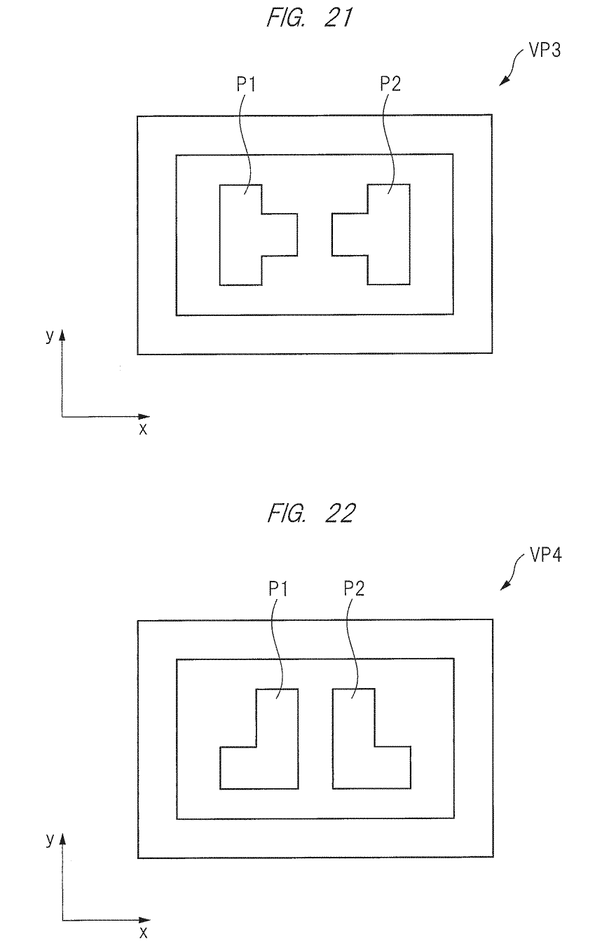

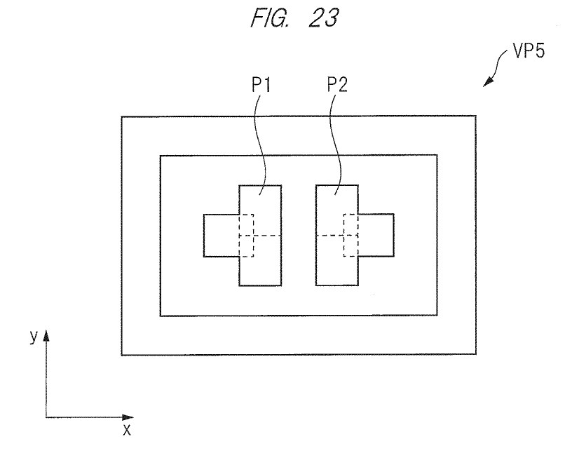

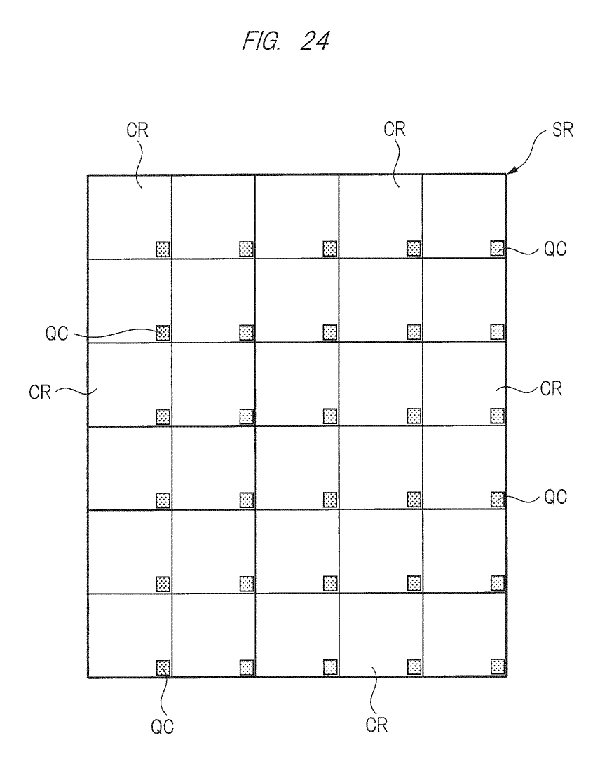

Note that the fundamental concept of the first embodiment is to provide the evaluation pattern that accurately reflects the presence or non-presence of a pattern defect in a portion of the product pattern caused by a slight deviation in the focal position. Further, the various specific configurations conforming to this fundamental concept without being limited to the evaluation pattern VP1 shown in FIG. 17 or the evaluation pattern VP2 shown in FIG. 18 make it capable to achieve a significant effect in which a pattern defect in a portion of the product pattern is detected with high accuracy. In other words, the fundamental concept of the first embodiment was made because it was found that the evaluation pattern VP1 shown in FIG. 17 and the evaluation pattern VP2 shown in FIG. 18 sensitively reacted when patterned in a state where the focal position was deviated. Further, a technical significance to use the evaluation pattern VP1 shown in FIG. 17 and the evaluation pattern VP2 shown in FIG. 18 resides in finding that a pattern defect appears even with a slight deviation in the focal position because the evaluation pattern VP1 shown in FIG. 17 and the evaluation pattern VP2 shown in FIG. 18 react more sensitively than the evaluation patterns of the line-and-space patterns shown in FIG. 13 or the fine dot patterns shown in FIG. 14 when patterned in a state where the focal position is deviated. This means that, qualitatively speaking, it was found that the evaluation pattern VP1 and the evaluation pattern VP2 have more convex portions than the line-and-space patterns or the fine dot patterns, and each convex portion has a tendency to blur while expanding due to focal position deviation. Namely, it can be understood that the evaluation pattern VP1 shown in FIG. 17 and the evaluation pattern VP2 shown in FIG. 18 are used to detect a pattern defect in a portion of the product pattern with high accuracy because the evaluation pattern VP1 and the evaluation pattern VP2 each have the convex portion that is likely to expand, whereby the evaluation pattern VP1 and the evaluation pattern VP2 are more likely to be bridged and cause a pattern defect than the line-and-space patterns or the fine dot patterns that do not have the convex portion. In other words, the evaluation pattern having the convex portion as in the evaluation pattern VP1 shown in FIG. 17 or the evaluation pattern VP2 shown in FIG. 18 is a pattern that is capable of accurately reflecting the presence or non-presence of a pattern defect in a portion of the product pattern caused by a slight deviation in the focal position. An evaluation pattern VP3 shown in FIG. 21 and an evaluation pattern VP4 shown in FIG. 22 can be given as examples of other specific configurations capable of achieving the fundamental concept of the first embodiment. For example, the evaluation pattern VP3 shown in FIG. 21 has a pattern P1 and a pattern P2 opposite to each other in the X direction (first direction), and the pattern P1 is constituted by a convex shape protruding in a direction toward the pattern P2 in the first direction. Additionally, an evaluation pattern VP5 shown in FIG. 23 is an example in which a pattern similar to the evaluation pattern VP1 shown in FIG. 17 is achieved by combining rectangular fine dot patterns. Specifically, the evaluation pattern VP5 shown in FIG. 23 has a pattern P1 and a pattern P2 opposite to each other in the X direction (first direction). Further, the pattern P1 is achieved by three fine dot patterns overlapping one another, and the pattern P2 is also achieved by three fine dot patterns overlapping one another. For example, the evaluation pattern VP1 shown in FIG. 17 can be used in the wiring process (forming processes for the first layer wiring, a second layer wiring, and a third layer wiring). In addition, the evaluation pattern VP5 shown in FIG. 23 can be used in, for example, the forming processes for an element isolation trench and a gate electrode pattern.

<Specifics on Application to Processes>

Next, a specific manufacturing process to which the fundamental concept of the first embodiment is applicable will be described. The fundamental concept of the first embodiment is applicable to the manufacturing process of the semiconductor device that comprises the steps of: (a) preparing the semiconductor substrate having the plurality of chip regions; (b) forming the film above the semiconductor substrate; (c) patterning the film; and (d) testing the patterned film. In particular, each of the chip regions within the semiconductor substrate prepared in the step (a) includes a product region in which the product pattern is formed and a monitor region in which the monitor pattern that is a separate pattern from the product pattern and has a shape corresponding to a portion of the product pattern is formed. At this time, in the step (c), a product configuration pattern partially configuring the product pattern is formed within the product region, and the monitor pattern is formed within the monitor region. Further, the monitor pattern has the evaluation pattern constituted by the first pattern and the second pattern opposite to each other in the first direction (X direction), and the first pattern is constituted by a convex shape protruding in the direction away from the second pattern in the first direction. Here, in the step (d), the product configuration pattern formed within the product region is tested for occurrence of a pattern defect based on the evaluation pattern included in the monitor pattern formed within the monitor region.

For example, the step (d) includes a step of determining that a pattern defect is occurring in the product configuration pattern when the first pattern and the second pattern of the evaluation pattern are bridged. Additionally, in the step (c), the photolithography technique is used.

Specifically, the step (c) has the steps of: (c1) applying the resist film over the film; (c2) performing the exposure process on the resist film; (c3) after the step (c2), performing the development process on the resist film; and (c4) after the step (c3), etching the film with using the patterned resist film as the mask to pattern the film. Further, in the step (c2), the exposure process is performed on the resist film, with a predetermined number of chip regions among the plurality of chip regions being used as a unit for one shot of exposure.

<<Application to Wiring Process>>

Further, the step (b) is a step in which the conductive film is formed over the interlayer insulating film formed above the semiconductor substrate, and the step (c) is a step in which the wiring pattern is formed on the interlayer insulating film. Namely, the fundamental concept of the first embodiment is applicable to, for example, the wiring process shown in FIGS. 8 and 9.

<<Application to Forming Process for Element Isolation Region>>

In addition, the step (b) is a step in which the insulating film is formed over the semiconductor substrate, and the step (c) is a step in which a mask pattern for forming the element isolation trench on the semiconductor substrate is formed. Namely, the fundamental concept of the first embodiment is applicable to, for example, the forming process for the element isolation trench shown in FIGS. 3 and 4.

<<Application to Forming Process for Gate Electrode>>

Additionally, the step (b) is a step in which the conductive film is formed over the gate insulating film formed over the semiconductor substrate, and the step (c) is a step in which the gate electrode pattern is formed on the gate insulating film. Namely, the fundamental concept of the first embodiment is applicable to, for example, the forming process for the gate electrode shown in FIGS. 5 and 6. In this case, the product pattern includes the gate electrode pattern formed on the semiconductor substrate with the gate insulating film interposed therebetween, and the monitor pattern is formed in the same layer as the gate electrode pattern.

### Second Embodiment

The fundamental concept of the above-described first embodiment is a concept that achieves the object in which a pattern defect in the product pattern caused by focal position deviation is detected with high accuracy. On the other hand, a fundamental concept of a second embodiment of the present invention is a concept that has a different approach than the fundamental concept of the above-described first embodiment and is based on the premise of achieving an object in which a pattern defect in the product pattern caused by location dependency of the focal position is detected with high accuracy.

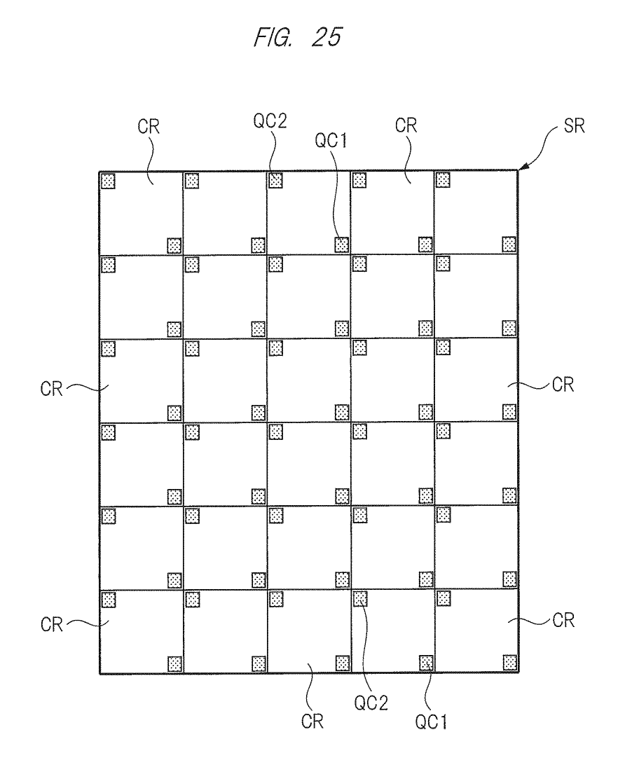

FIG. 25 is a schematic diagram showing a one-shot region SR that indicates a single exposure region corresponding to a unit for one projection in the exposure process of the photolithography technique. As shown in FIG. 25, a plurality of chip regions CR within the semiconductor substrate (semiconductor wafer) are included in the one-shot region SR. Namely, the exposure process of the photolithography technique is simultaneously performed on a predetermined number of chip regions CR.

In this regard, the one-shot region SR is a spacious region that includes the predetermined number of chip regions CR. Further, in the exposure process, a mask pattern of a mask arranged in an exposure system is projected onto the predetermined number of chip regions CR in the one-shot region SR via a reduction lens system. At this time, lens aberration occurs in the reduction lens system, and this aberration may cause deviation between, for example, the focal position of the chip region CR arranged at a central region of the one-shot region SR and the focal position of the chip region CR arranged at an end region of the one-shot region SR. For this reason, even if a pattern defect does not occur in the product pattern within the chip region CR arranged at, for example, the central region of the one-shot region SR, it is possible for location dependency of the focal position to cause a pattern defect to occur in the product pattern within the chip region CR arranged at the end region of the one-shot region SR.

Therefore, if the monitor pattern is formed at, for example, only one location within the one-shot region SR, location dependency of the focal position due to lens aberration may cause a pattern defect to occur in the product pattern within the chip region CR arranged at a position distant from this monitor pattern, even if a pattern defect does not occur in the evaluation pattern included in the monitor pattern. Namely, if the monitor pattern were provided at only one location within the one-shot region SR, it would be impossible to detect a pattern defect in all of the product patterns within the predetermined number of chip regions CR in the one-shot region SR by using the evaluation pattern included in this monitor pattern.

For this reason, as shown in FIG. 24, it is considered that the monitor pattern QC is formed within, for example, each of the chip regions CR in the one-shot region SR. In this case, a pattern defect in the chip region CR arranged at, for example, the central region of the one-shot region SR can be detected based on the evaluation pattern of the monitor pattern QC arranged within this chip region CR. Likewise, a pattern defect in the chip region CR arranged at the end region of the one-shot region SR can be detected based on the evaluation pattern of the monitor pattern QC arranged within this chip region CR. Namely, as shown in FIG. 24, in a configuration in which the monitor pattern QC is formed within each chip region CR in the one-shot region SR, the pattern is less likely to be affected by location dependency of the focal position due to lens aberration, and accordingly, all pattern defects in the product pattern within each chip region CR in the one-shot region SR can be detected with high accuracy. Note that, even if the monitor pattern QC is formed within each chip region CR in the one-shot region SR as shown in FIG. 24, it is considered that there may be a case where this is insufficient in regards to detecting a pattern defect in all of the product patterns formed within an individual chip region CR. Namely, if all of the product patterns formed within an individual chip region CR are evaluated for a pattern defect by using only the evaluation pattern of a single monitor pattern provided within each of the chip regions, it is considered that an influence by location dependency of the focal position due to lens aberration cannot be sufficiently removed. For this reason, as shown in FIG. 25, each of the chip regions CR in the one-shot region SR of the second embodiment is provided with, for example, a plurality of monitor patterns (QC1, QC2) instead of being provided with a single monitor pattern. Namely, a feature of the second embodiment is that an individual semiconductor chip (chip region before singulation) has a plurality of monitor regions in which monitor patterns that are separate patterns from the product pattern and have a shape corresponding to a portion of the product pattern are formed. Hence, according to the second embodiment, the evaluation pattern included in, for example, the monitor pattern QC1 within the chip region CR can be used to detect a pattern defect in the product pattern arranged at a region closer to the monitor pattern QC1 than to the monitor pattern QC2. On the other hand, the evaluation pattern included in the monitor pattern QC2 within the chip region CR can be used to detect a pattern defect in the product pattern arranged at a region closer to the monitor pattern QC2 than to the monitor pattern QC1. Hence, according to the second embodiment, it is possible to further suppress a mismatch between the presence or non-presence of a pattern defect in the evaluation pattern and the presence or non-presence of a pattern defect in the product pattern caused by location dependency of the focal position. As a result, an object of the second embodiment in which a pattern defect in the product pattern caused by location dependency of the focal position is detected with high accuracy is sufficiently achieved by an approach that differs from the approach of the above-described first embodiment.

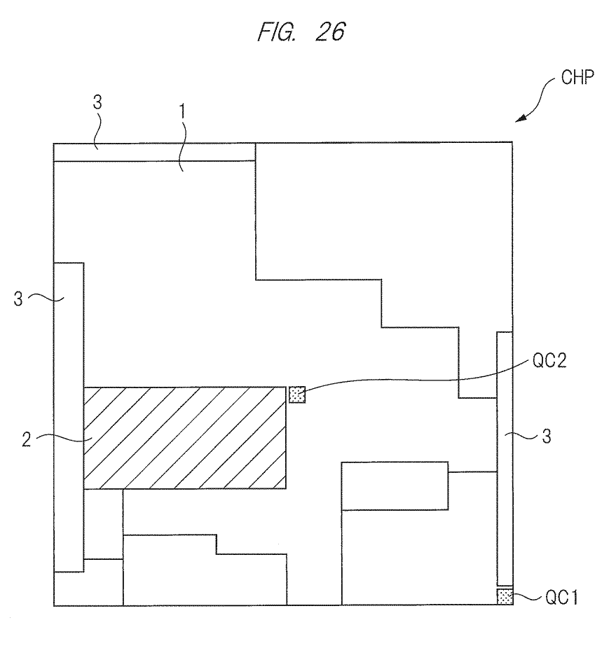

In particular, the fundamental concept of the second embodiment is not limited to a configuration in which, for example, the plurality of monitor regions are respectively formed at corner portions of each rectangular semiconductor chip (chip region CR before singulation) as shown in FIG. 25. Specifically, as shown in FIG. 26, the monitor pattern QC1 can be arranged in, for example, the vicinity of a corner portion of the semiconductor chip CHP, whereas the monitor pattern QC2 can be arranged closer to the vicinity of the logic circuit region in which the logic circuit 2 composed of a high density pattern is formed than to a circuit other than the logic circuit 2. Hence, in order to detect a pattern defect in the high-density product pattern configuring the logic circuit 2, the evaluation pattern included in the monitor pattern QC2 arranged in the vicinity of the logic circuit 2 is used, whereby a pattern defect in the product pattern caused by location dependency of the focal position can be detected with high accuracy.

In the foregoing, the invention made by the present inventors has been concretely described based on the embodiments. However, it is needless to say that the present invention is not limited to the foregoing embodiments, and various modifications and alterations can be made within the scope of the present invention.

The foregoing embodiments include the following form.

(Additional Statement)

A semiconductor device including a semiconductor chip on which a monitor pattern that is a separate pattern from a product pattern is formed,

wherein the monitor pattern has an evaluation pattern constituted by a first pattern and a second pattern opposite to each other in a first direction, and

the first pattern is constituted by a convex shape protruding in a direction toward the second pattern in the first direction.

What is claimed is:

1. A semiconductor device comprising:
a semiconductor chip on which a product pattern and a monitor pattern that is a separate pattern from the product pattern are formed,
wherein the monitor pattern has an evaluation pattern constituted by a first pattern and a second pattern opposite to each other in a first direction, and
the first pattern is constituted by a convex shape protruding in a direction away from the second pattern in the first direction.

2. The semiconductor device according to claim 1,
wherein the second pattern is constituted by a rectangular shape.

3. The semiconductor device according to claim 1,
wherein the second pattern is constituted by a convex shape protruding in a direction away from the first pattern in the first direction.

4. The semiconductor device according to claim 1,
wherein the product pattern has a first layer wiring pattern formed above a semiconductor substrate, and
the monitor pattern is formed in the same layer as the first layer wiring pattern.

5. The semiconductor device according to claim 1,
wherein the product pattern has a gate electrode pattern formed on a semiconductor substrate with a gate insulating film interposed therebetween, and
the monitor pattern is formed in the same layer as the gate electrode pattern.

6. A semiconductor device comprising:
a semiconductor chip on which a product pattern and a monitor pattern that is a separate pattern from the product pattern are formed,
wherein the semiconductor chip has a plurality of monitor regions in which the monitor pattern is formed.

7. The semiconductor device according to claim 6,
wherein the semiconductor chip is rectangular in shape, and
the plurality of monitor regions are respectively formed at corner portions of the semiconductor chip.

8. The semiconductor device according to claim 6,
wherein the product pattern has:
a logic circuit pattern corresponding to a logic circuit; and
a circuit pattern corresponding to a circuit that is separate from the logic circuit, and
at least one monitor region among the plurality of monitor regions is located closer to the logic circuit pattern than to the circuit pattern.

9. The semiconductor device according to claim 6,
wherein the monitor pattern has an evaluation pattern constituted by a first pattern and a second pattern opposite to each other in a first direction, and
the first pattern is constituted by a convex shape protruding in a direction away from the second pattern in the first direction.

10. A method of manufacturing a semiconductor device, comprising the steps of:
(a) preparing a semiconductor substrate having a plurality of chip regions;
(b) forming a film above the semiconductor substrate;
(c) patterning the film; and
(d) testing the patterned film,
wherein each of the chip regions within the semiconductor substrate prepared in the step (a) includes:
a product region in which a product pattern is formed; and
a monitor region in which a monitor pattern that is a separate pattern from the product pattern is formed, the monitor pattern having an evaluation pattern constituted by a first pattern and a second pattern opposite to each other in a first direction, the first pattern being constituted by a convex shape protruding in a direction away from the second pattern in the first direction,
in the step (c), a product configuration pattern partially configuring the product pattern is formed within the product region, and the monitor pattern is formed within the monitor region, and
in the step (d), the product configuration pattern formed within the product region is tested for occurrence of a pattern defect based on the evaluation pattern included in the monitor pattern formed within the monitor region.

11. The method of manufacturing a semiconductor device according to claim 10,
wherein the step (d) includes a step of determining that a pattern defect is occurring in the product configuration pattern when the first pattern and the second pattern in the evaluation pattern are bridged.

12. The method of manufacturing a semiconductor device according to claim 10,
wherein in the step (c), a photolithography technique is used.

13. The method of manufacturing a semiconductor device according to claim 12,
wherein the step (c) has the steps of:
(c1) applying a resist film over the film;
(c2) performing an exposure process on the resist film;
(c3) after the step (c2), performing a development process on the resist film; and
(c4) after the step (c3), etching the film with using the patterned resist film as a mask to pattern the film, and
in the step (c2), the exposure process is performed on the resist film, with a predetermined number of chip regions among the plurality of chip regions being used as a unit for one shot of exposure.

14. The method of manufacturing a semiconductor device according to claim 10,
wherein the step (b) is a step in which a conductive film is formed over an interlayer insulating film formed above the semiconductor substrate, and
the step (c) is a step in which a wiring pattern is formed on the interlayer insulating film.

15. The method of manufacturing a semiconductor device according to claim 10,
wherein the step (b) is a step in which an insulating film is formed over the semiconductor substrate, and
the step (c) is a step in which a mask pattern for forming an element isolation trench on the semiconductor substrate is formed.

16. The method of manufacturing a semiconductor device according to claim 10,
wherein the step (b) is a step in which a conductive film is formed over agate insulating film formed over the semiconductor substrate, and
the step (c) is a step in which a gate electrode pattern is formed on the gate insulating film.
